(19) United States
(12) Patent Application Publication
(10) Pub. No.: US 2016/0268545 A1
(43) Pub. Date: Sep. 15, 2016

(54) ORGANIC ELECTROLUMINESCENT ELEMENT, LIGHTING DEVICE, AND LIGHTING SYSTEM

(71) Applicant: Kabushiki Kaisha Toshiba, Minato-ku (JP)

(72) Inventors: Tomoko SUGIZAKI, Kawasaki (JP); Keiji SUGI, Fujisawa (JP); Akio AMANO, Machida (JP); Yasushi SHINJO, Kawasaki (JP)

(73) Assignee: Kabushiki Kaisha Toshiba, Minato-ku (JP)

(21) Appl. No.: 15/163,982

(22) Filed: May 25, 2016

Related U.S. Application Data
(63) Continuation of application No. PCT/JP2013/081936, filed on Nov. 27, 2013.

(51) Int. Cl. H01L 51/52; H01L 27/32

(52) U.S. Cl. CPC H01L 51/5253; H01L 51/5246; H01L 51/5259; H01L 51/5206; H01L 51/5221; H01L 27/3204; H01L 27/3202; H01L 2251/5361

(57) ABSTRACT

According to one embodiment, an organic electroluminescent element includes a first electrode, a first insulating layer, an organic layer, a second electrode, and a second insulating layer. The first insulating layer is provided on the first electrode. The first insulating layer has an opening. The organic layer is provided on the first electrode. At least a portion of the organic layer is provided in the opening. At least a portion of the second electrode is provided on the organic layer. A second insulating layer covers at least a portion of an outer edge of the first insulating layer. A density of the second insulating layer is higher than a density of the first insulating layer.

### CROSS-REFERENCE TO RELATED APPLICATIONS

This is a continuation application of International Application PCT/JP2013/081936, filed on Nov. 27, 2013; the entire contents of which are incorporated herein by reference.

### FIELD

Embodiments described herein relate generally to an organic electroluminescent element, lighting device, and lighting system.

### BACKGROUND

There is an organic electroluminescent element that includes a light-transmissive first electrode, a second electrode, and an organic layer provided between the first electrode and the second electrode. There is a lighting device that uses the organic electroluminescent element as a light source. There is a lighting system that includes multiple organic electroluminescent elements and a controller that controls the lit state and the unlit state of the multiple organic electroluminescent elements. In the organic electroluminescent element, it is desirable to suppress the penetration of moisture into the organic layer and increase the storage life.

### BRIEF DESCRIPTION OF THE DRAWINGS

FIG. 1A and FIG. 1B are cross-sectional views schematically showing an organic electroluminescent element according to a first embodiment;

FIG. 2 is a plan view schematically showing portions of the organic electroluminescent element according to the first embodiment;

FIG. 3 is a plan view schematically showing portions of the organic electroluminescent element according to the first embodiment;

FIG. 4 is a schematic cross-sectional view showing a portion of the organic electroluminescent element according to the first embodiment;

FIG. 5 is a plan view schematically showing a portion of another organic electroluminescent element according to the first embodiment;

FIG. 6 is a cross-sectional view schematically showing another organic electroluminescent element according to the first embodiment;

FIG. 7A and FIG. 7B are schematic views showing another organic electroluminescent element according to the first embodiment;

FIG. 8 is a cross-sectional view schematically showing another organic electroluminescent element according to the first embodiment;

FIG. 9 is a cross-sectional view schematically showing another organic electroluminescent element according to the first embodiment;

FIG. 10A and FIG. 10B are cross-sectional views schematically showing another organic electroluminescent element according to the first embodiment;

FIG. 11A and FIG. 11B are cross-sectional views schematically showing other organic electroluminescent elements according to the first embodiment;

FIG. 12 is a cross-sectional view schematically showing another organic electroluminescent element according to the first embodiment;

FIG. 13 is schematic views showing a lighting device according to a second embodiment; and

FIG. 14A to FIG. 14C are schematic views showing lighting systems according to a third embodiment.

### DETAILED DESCRIPTION

According to one embodiment, an organic electroluminescent element includes a first electrode, a first insulating layer, an organic layer, a second electrode, and a second insulating layer. The first insulating layer is provided on the first electrode. The first insulating layer has an opening. The organic layer is provided on the first electrode. At least a portion of the organic layer is provided in the opening. At least a portion of the second electrode is provided on the organic layer. A second insulating layer covers at least a portion of an outer edge of the first insulating layer. A density of the second insulating layer is higher than a density of the first insulating layer.

Various embodiments will be described hereinafter in detail with reference to the accompanying drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

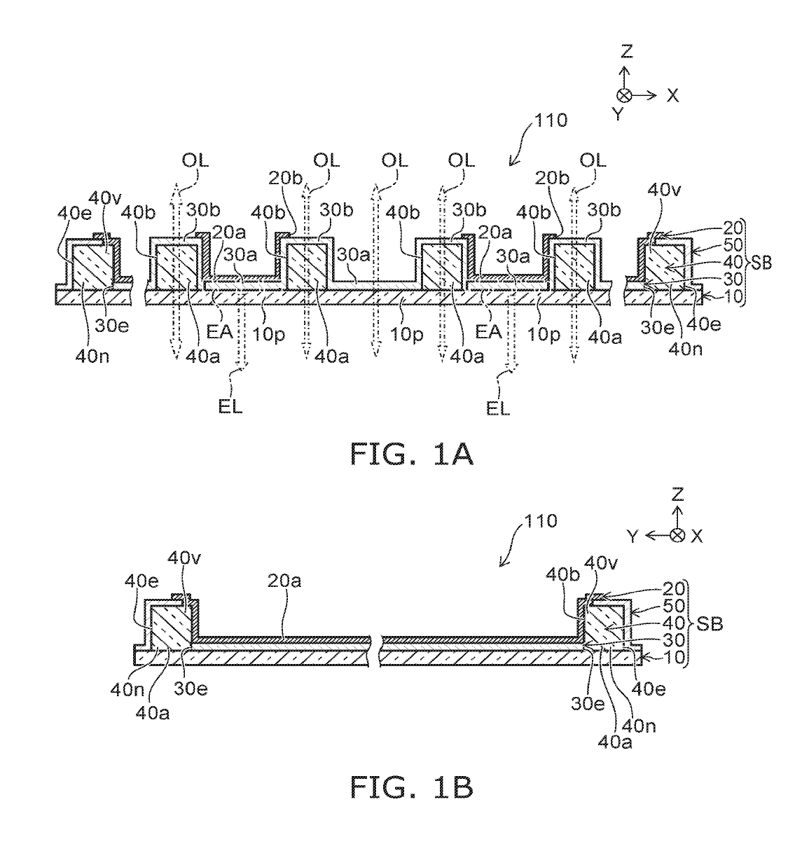

FIG. 1A and FIG. 1B are cross-sectional views schematically showing an organic electroluminescent element according to a first embodiment.

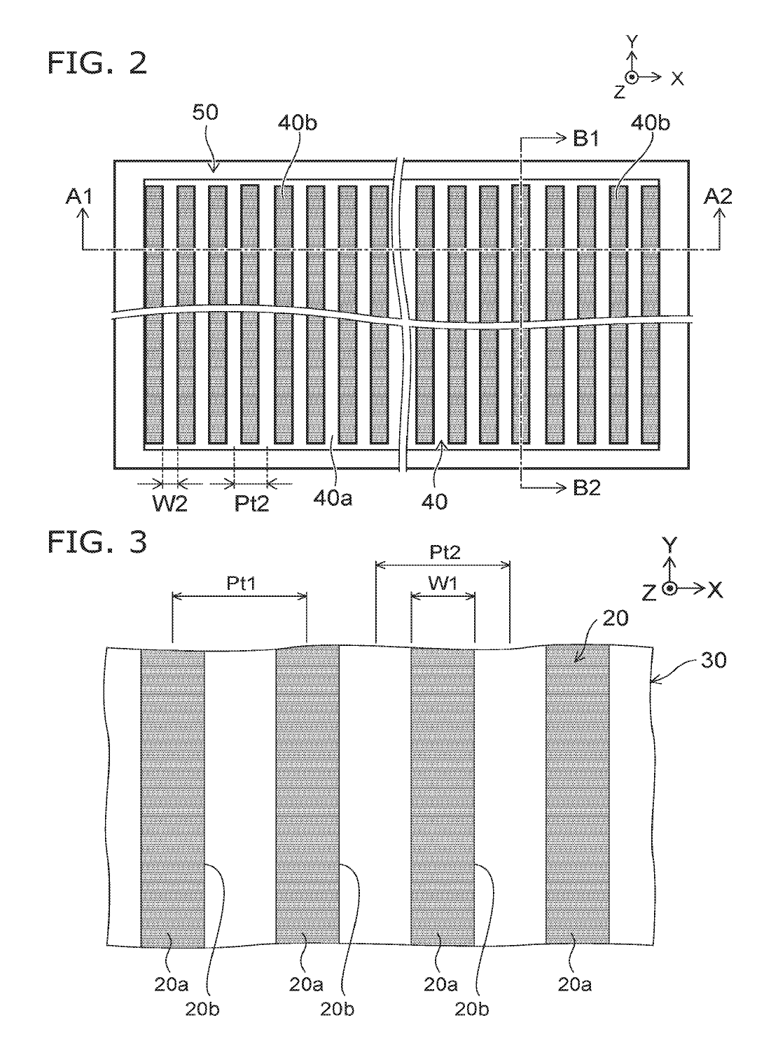

FIG. 2 and FIG. 3 are plan views schematically showing portions of the organic electroluminescent element according to the first embodiment.

As shown in FIG. 1A, FIG. 1B, FIG. 2, and FIG. 3, the organic electroluminescent element 110 includes a stacked body SB. The stacked body SB includes a first electrode 10, a second electrode 20, an organic layer 30, a first insulating layer 40, and a second insulating layer 50.

FIG. 2 shows only the first insulating layer 40 and the second insulating layer 50 for convenience. FIG. 1A corresponds to a line A1-A2 cross section of FIG. 2. FIG. 1B corresponds to a line B1-B2 cross section of FIG. 2. FIG. 3 shows only the second electrode 20 and the organic layer 30 for convenience. These drawings show enlarged portions of the organic electroluminescent element according to the embodiment.

The first electrode 10 is, for example, light-transmissive. The first electrode 10 is, for example, a transparent electrode. The second electrode 20 is arranged with the first electrode 10 in a first direction. The organic layer 30 is provided between the first electrode 10 and the second electrode 20. The organic layer 30 includes an organic light-emitting layer. The organic layer 30 is light-transmissive. The organic layer 30 is, for example, light-transmissive in the unlit state.

Here, a direction parallel to the stacking direction (the first direction) of the first electrode 10, the second electrode 20, and the organic layer 30 is taken as a Z-axis direction. One direction perpendicular to the Z-axis direction is taken as an X-axis direction. A direction perpendicular to the X-axis direction and the Z-axis direction is taken as a Y-axis direction. The Z-axis direction corresponds to the thickness direction of the first electrode 10.

In the example, the second electrode 20 includes a conductive a and multiple openings 20b (first openings). A portion of the organic layer 30 is exposed in the openings 20b. In the example, the second electrode 20 includes multiple conductive portions 20a. The multiple conductive portions 20a extend in the Y-axis direction (a second direction) and are arranged in the X-axis direction (a third direction). The multiple openings 20b are disposed respectively in the regions between the multiple conductive portions 20a. For example, each of the multiple openings 20b has a trench configuration extending in the Y-axis direction. In other words, in the example, the second electrode 20 has a stripe configuration.

The second electrode 20 may not have the openings 20b; and a portion of the organic layer 30 may not be exposed from the second electrode 20. In other words, the second electrode 20 may cover the upper surface of the organic layer 30.

The second electrode 20 (the conductive portion 20a) is, for example, light-reflective. The light reflectance of the second electrode 20 is higher than the light reflectance of the first electrode 10. In this specification, the state in which the light reflectance is higher than the light reflectance of the first electrode 10 is called light-reflective.

In the example, the first insulating layer 40 is provided between the first electrode 10 and the organic layer 30. In other words, the first insulating layer 40 is provided on the first electrode 10. The organic layer 30 is provided on the first insulating layer 40. The first insulating layer 40 includes, for example, an insulating portion 40a and an opening 40b (a second opening). A portion of the first electrode 10 is exposed in the opening 40b. When projected onto the X-Y plane (a plane perpendicular to the first direction), the opening 40b is disposed at a position overlapping the conductive portion 20a of the second electrode 20. In other words, when viewed in the Z-axis direction, the opening 40b is disposed at a position overlapping the conductive portion 20a. The first insulating layer 40 is light-transmissive. The first insulating layer 40 is, for example, transparent.

In the example, the first insulating layer 40 includes multiple openings 40b. The multiple openings 40b extend in the Y-axis direction and are arranged in the X-axis direction. For example, each of the multiple openings 40b has a trench configuration. The insulating portion 40a is a lattice configuration that surrounds each of the multiple openings 40b. For example, the first insulating layer 40 has a stripe configuration. In the example, multiple portions of the first electrode 10 are respectively exposed in the multiple openings 40b. Hereinbelow, the portions of the first electrode 10 exposed in the openings 40b are called exposed portions 10p.

In the example, when projected onto the X-Y plane, each of the multiple conductive portions 20a overlaps one of the multiple openings 40b. In the example, when projected onto the X-Y plane, at least one opening 40b is disposed in each region between the multiple conductive portions 20a. More specifically, when projected onto the X-Y plane, one opening 40b is disposed in each region between the multiple conductive portions 20a. When projected onto the X-Y plane, the number of the openings 40b disposed in each region between the multiple conductive portions 20a may be two or more. When projected onto the X-Y plane, the multiple conductive portions 20a may respectively overlap the multiple openings 40b. In other words, it is unnecessary for the openings 40b to be disposed only between the multiple conductive portions 20a.

When projected onto the X-Y plane, the organic layer 30 includes a first portion 30a that overlaps the opening 40b of the first insulating layer 40, and a second portion 30b that overlaps the insulating portion 40a. For example, the organic layer 30 is provided to be continuous on the insulating portion 40a and on each of the multiple exposed portions 10p. Thus, at least a portion of the organic layer 30 is provided in the openings 40b on the first electrode 10. At least a portion of the second electrode 20 is provided on the at least a portion of the organic layer 30 provided in the openings 40b.

The organic layer 30 may not overlap the insulating portion 40a. In other words, the organic layer 30 may be provided only in the openings 40b of the first insulating layer 40.

In the example, the first portion 30a of the organic layer 30 is interposed between the insulating portion 40a. As shown in FIG. 1A, a portion of the insulating portion 40a is covered with an outer edge 30e of the organic layer 30 at two X-axis direction ends. In the example, the outer edge 30e of the organic layer 30 is exposed from the opening 20b of the second electrode 20. As shown in FIG. 1B, the insulating portion 40a covers the outer edge 30e at the two ends in the Y-axis direction of the organic layer 30 at the first portion 30a.

The thickness (the length along the Z-axis direction) of the organic layer 30 is thinner than the thickness of the first insulating layer 40 (the insulating portion 40a). The distance in the Z-axis direction between the interface between the first electrode 10 and the first portion 30a of the organic layer 30 (the lower surface of the first portion 30a) and the interface between the second electrode 20 of the first portion 30a (the upper surface of the first portion 30a) is shorter than the distance in the Z-axis direction between the first electrode 10 and the end portion in the Z-axis direction of the insulating portion 40a of the insulating layer 40. In other words, the interface between the first portion 30a and the second electrode 20 (the upper surface of the first portion 30a) is positioned lower than the end portion of the insulating portion 40a on the side opposite to the first electrode 10 side (the upper surface of the insulating portion 40a). Thereby, for example, when forming the second electrode 20, undesirable scratching of the organic layer 30 can be suppressed.

The second insulating layer 50 covers at least a portion of an outer edge 40e of the first insulating layer 40. For example, the second insulating layer 50 contacts the first insulating layer 40. The density of the second insulating layer 50 is higher than the density of the first insulating layer 40. The first insulating layer 40 includes, for example, an organic insulating material. The second insulating layer 50 includes, for example, an inorganic insulating material. The density of the second insulating layer 50 is, for example, not less than 2 g/cm³ and not more than 3.5 g/cm³. The density of the first insulating layer 40 is, for example, not less than 1 g/cm³ and not more than 2.5 g/cm³. The second insulating layer 50 is light-transmissive. The second insulating layer 50 is, for example, transparent.

It is sufficient for the density of the second insulating layer 50 to be even a little higher than the density of the first insulating layer 40; and it is favorable for the density of the second insulating layer 50 to be not less than 1.3 times the density of the first insulating layer 40. For example, in the case where the first insulating layer 40 includes polytetrafluoroethylene and the second insulating layer 50 includes SiON, the film density of the first insulating layer 40 is 2.2 g/cm³; and the film density of the second insulating layer 50 is 3 g/cm³. Accordingly, in such a case, the density of the second insulating layer 50 is 1.36 times the density of the first insulating layer 40. For example, in the case where the first insulating layer 40 includes polyimide and the second insulating layer 50 includes SiO₂, the film density of the first insulating layer 40 is 1.4 g/cm³; and the film density of the second insulating layer 50 is 2.2 g/cm³. Accordingly, in such a case, the density of the second insulating layer 50 is 1.57 times the density of the first insulating layer 40. However, the densities of the first insulating layer 40 and the second insulating layer 50 change due to the formation method, the film formation conditions, etc.

The first insulating layer 40 includes a laminated portion 40v and a non-laminated portion 40n. When projected onto the X-Y plane, the laminated portion 40v overlaps at least one of the organic layer 30 or the second electrode 20. The non-laminated portion 40n is the portion of the first insulating layer 40 other than the laminated portion 40v. In other words, when projected onto the X-Y plane, the non-laminated portion 40n does not overlap the organic layer 30 or the second electrode 20. The organic layer 30 may overlap the non-laminated portion 40n. For example, the non-laminated portion 40n is an end portion of the first insulating layer 40 in any direction perpendicular to the Z-axis direction. The second insulating layer 50 covers the non-laminated portion 40n of the first insulating layer 40.

As shown in FIG. 2, the second insulating layer 50 has an annular configuration surrounding the first insulating layer 40. For example, the second insulating layer 50 covers the entire non-laminated portion 40n of the first insulating layer 40. For example, the second insulating layer 50 covers the entire portion of the first insulating layer 40 not covered with the first electrode 10, the second electrode 20, and the organic layer 30. The non-laminated portion 40n includes the outer edge 40e of the first insulating layer 40. For example, the second insulating layer 50 covers the entire outer edge 40e of the first insulating layer 40. The second insulating layer 50 may not necessarily have an annular configuration. For example, a portion of the configuration may be discontinuous.

The organic layer 30 is electrically connected to the first electrode 10 via each of the multiple openings 40b. For example, the multiple first portions 30a of the organic layer 30 respectively contact the multiple exposed portions 10p of the first electrode 10. Thereby, the organic layer 30 is electrically connected to the first electrode 10.

The organic layer 30 is electrically connected to the second electrode 20. For example, the organic layer 30 contacts each of the multiple conductive portions 20a. Thereby, the organic layer 30 is electrically connected to the second electrode 20. In this specification, being “electrically connected” includes not only the case of being in direct contact but also the case where another conductive member or the like is interposed therebetween.

A current is caused to flow in the organic layer 30 by using the first electrode 10 and the second electrode 20. Thereby, the organic layer 30 emits light. For example, the organic layer 30 generates excitons by electrons and holes recombining when the current flows. For example, the organic layer 30 emits light by utilizing the emission of light when radiative deactivation of the excitons occurs.

In the organic electroluminescent element 110, the portion of the organic layer 30 between the exposed portion 10p and the conductive portion 20a is a light-emitting region EA. In the example, the organic layer 30 includes the multiple light-emitting regions EA between the multiple exposed portions 10p and the multiple conductive portions 20a. Emitted light EL that is emitted from the light-emitting regions EA is emitted outside the organic electroluminescent element 110 via the first electrode 10. A portion of the emitted light EL is reflected by the second electrode 20 and emitted to the outside via the organic layer 30 and the first electrode 10. In other words, the organic electroluminescent element 110 is a single-side emitting type.

Also, in the organic electroluminescent element 110, outside light OL that enters from the outside passes through the first electrode 10, the organic layer 30, and the first insulating layer 40 in each portion between the multiple conductive portions 20a. Thus, the organic electroluminescent element 110 transmits the outside light OL entering the organic electroluminescent element 110 from the outside while emitting the emitted light EL. Thus, the organic electroluminescent element 110 is light-transmissive. Thereby, in the organic electroluminescent element 110, the image of the background can be visually confirmed via the organic electroluminescent element 110. In other words, the organic electroluminescent element 110 is a light source having a thin-film configuration or a plate configuration that can be see-through.

Thus, according to the organic electroluminescent element 110 of the embodiment, a light-transmissive organic electroluminescent element can be provided. In the case where the organic electroluminescent element 110 is applied to a lighting device, various new applications other than the lighting function become possible due to the function of transmitting the background image.

For example, the light emission characteristics of the organic EL material included in the organic layer 30 degrade due to moisture. For example, when the organic electroluminescent element is operated for a long time, the luminance decreases at the location of the organic layer degrading due to moisture. The degraded portion substantially no longer emits light. So-called dark spots occur. As time elapses, the dark spots grow and become defects.

To suppress the occurrence or growth of the dark spots in the organic electroluminescent element, the penetration of moisture into the organic layer is suppressed and/or the moisture that has penetrated into the element is removed. For example, the penetration of moisture into the organic layer from the outside is suppressed by sealing, with a sealing substrate, the element substrate where the organic layer is formed. For example, a desiccant is mounted in a sealed space made by bonding the element substrate to the sealing substrate to remove the moisture that has penetrated into the element. For example, this is called hollow sealing.

There is also a countermeasure called solid sealing. In solid sealing, the sealing material is filled around the stacked body including the organic layer directly without a space. Therefore, a gap that allows moisture or the like to penetrate does not remain between the substrates holding the stacked body interposed between the substrates; and the degradation of the element can be suppressed more appropriately.

In the organic electroluminescent element, the outer edge of the organic layer is surrounded with an insulating layer (the first insulating layer 40). For example, the insulating layer is used to regulate the light-emitting region and protect the organic layer when manufacturing. The degradation of the organic electroluminescent element including such an insulating layer is promoted compared to an element in which the insulating layer is not used.

The inventor of the application performed diligent investigations of the degradation from the outer edge of the organic layer and discovered that the density of the insulating layer is one cause of the degradation of the organic layer. The insulating layer includes, for example, a material having a relatively low density such as an organic insulating material, etc. Therefore, it is considered that in the case where the insulating layer is on the outer side of the organic layer, the moisture undesirably penetrates the organic layer via the insulating layer when moisture penetrates the insulating layer. For example, it is considered that the insulating layer promotes the degradation of the organic layer. This new problem was discovered by the investigation of the inventor of the application.

It also may be considered to include a material having a relatively high density such as an inorganic insulating material, etc., in the insulating layer surrounding the organic layer. However, in the case where the inorganic insulating material is used, for example, the formation of the insulating layer is difficult. For example, this may undesirably increase the manufacturing cost.

Conversely, in the organic electroluminescent element 110 according to the embodiment, at least a portion of the outer edge 30e of the organic layer 30 is covered with the insulating portion 40a of the first insulating layer 40; and at least a portion of the outer edge 40e of the first insulating layer 40 is covered with the second insulating layer 50. The density of the second insulating layer 50 is set to be higher than the density of the first insulating layer 40. For example, the first insulating layer 40 includes an organic insulating material; and the second insulating layer 50 includes an inorganic insulating material.

Thereby, in the organic electroluminescent element 110 according to the embodiment, the penetration of the moisture into the outer edge 30e of the organic layer 30 can be suppressed by the second insulating layer 50. For example, the storage life of the organic electroluminescent element 110 can be longer. For example, compared to the case where the first insulating layer 40 includes the inorganic insulating material, etc., the formation of the first insulating layer 40 and the second insulating layer 50 is easy. For example, the increase of the manufacturing cost of the organic electroluminescent element 110 can be suppressed.

In the example, the configuration of the organic electroluminescent element 110 projected onto the X-Y plane is a quadrilateral configuration. The configuration of the organic electroluminescent element 110 is not limited thereto and may be, for example, a circle or an ellipse. Or, another polygonal configuration such as a triangular configuration, a hexagonal configuration, etc., may be used. In other words, the configuration of the organic electroluminescent element 110 projected onto the X-Y plane may be any configuration.

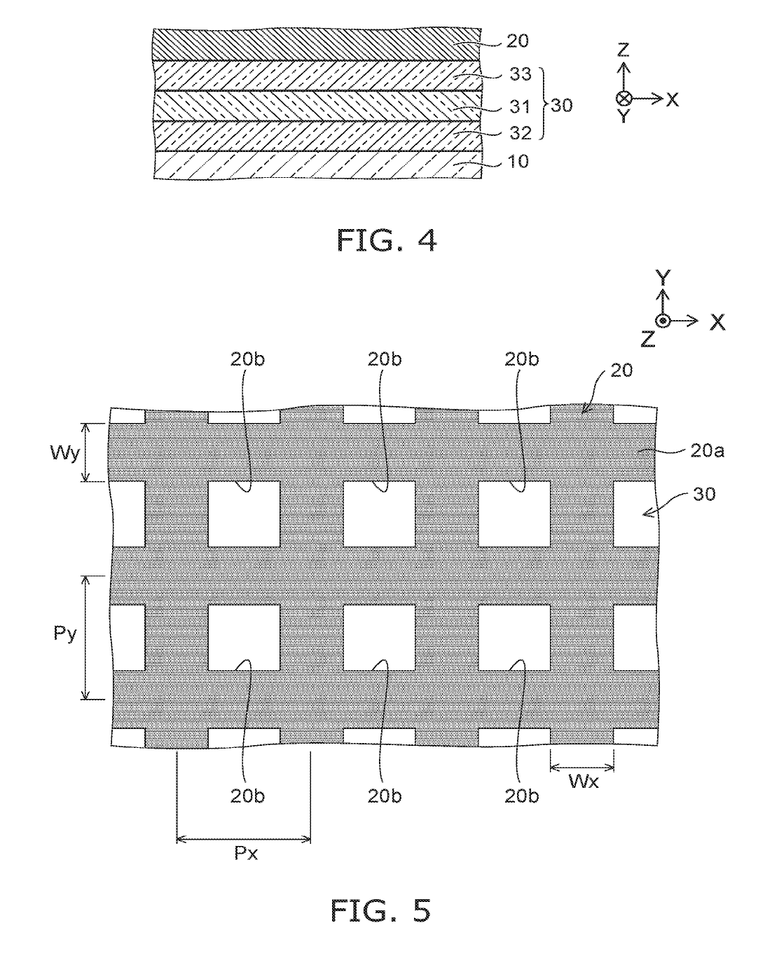

FIG. 4 is a schematic cross-sectional view showing a portion of the organic electroluminescent element according to the first embodiment.

As shown in FIG. 4, the organic layer 30 includes a first layer 31. The organic layer 30 may further include at least one of a second layer 32 or a third layer 33 as necessary. The first layer 31 emits light of a wavelength of visible light. The second layer 32 is provided between the first layer 31 and the first electrode 10. The third layer 33 is provided between the first layer 31 and the second electrode 20.

The first layer 31 may include, for example, a material such as Alq₃ (tris(8-hydroxyquinolinolato)aluminum), F8BT (poly(9,9-dioctylfluorene-co-benzothiadiazole), PPV (polyparaphenylene vinylene), etc. The first layer 31 may include a mixed material of a host material and a dopant added to the host material. For example, CBP (4,4′-N,N′-bis dicarbazolyl-biphenyl), BCP (2,9-dimethyl-4,7 diphenyl-1,10-phenanthroline), TPD (4,4′-bis-N-3 methyl phenyl-N-phenylamino biphenyl), PVK (polyvinyl carbazole), PPT (poly(3-phenylthiophene)), etc., may be used as the host material. For example, Flrpic (iridium(III)-bis(4,6-di-fluorophenyl)-pyridinate-N,C2′-picolinate), Ir(ppy)₃ (tris(2-phenylpyridine)iridium), Flr6 (bis(2,4-difluorophenylpyridinato)-tetrakis(1-pyrazolyl)borate-iridium(III)), etc., may be used as the dopant material. The first layer 31 is not limited to these materials.

For example, the second layer 32 functions as a hole injection layer. The hole injection layer includes, for example, at least one of PEDPOT:PPS (poly(3,4-ethylenedioxythiophene)-poly(styrenesulfonic acid)), CuPc (copper phthalocyanine), MoO₃ (molybdenum trioxide) or the like. For example, the second layer 32 functions as a hole transport layer. The hole transport layer includes, for example, at least one of α-NPD (4,4′-bis[N-(1-naphthyl)-N-phenylamino]biphenyl), TAPC (1,1-bis[4-[N,N-di(p-tolyl)amino]phenyl]cyclohexane), m-MTDATA (4,4′,4″-tris[phenyl(m-tolyl)amino]triphenylamine), TPD (bis(3-methyl phenyl)-N,N′-diphenylbenzidine), TCTA (4,4′,4″-tri(N-carbazolyl)triphenylamine), or the like. For example, the second layer 32 may have a stacked structure of a layer that functions as a hole injection layer and a layer that functions as a hole transport layer. The second layer 32 may include a layer other than the layer that functions as the hole injection layer and the layer that functions as the hole transport layer. The second layer 32 is not limited to these materials.

For example, the third layer 33 may include a layer that functions as an electron injection layer. The electron injection layer includes, for example, at least one of lithium fluoride, cesium fluoride, lithium quinoline complex, or the like. The third layer 33 may include, for example, a layer that functions as an electron transport layer. The electron transport layer includes, for example, at least one of Alq3 (tris(8 quinolinolato)aluminum(III)), BAlq (bis(2-methyl-8-quinolilato)(p-phenylphenolate)aluminum), Bphen (bathophenanthroline), 3TPYMB (tris[3-(3-pyridyl)-mesityl]borane), or the like. For example, the third layer 33 may have a stacked structure of a layer that functions as an electron injection layer and a layer that functions as an electron transport layer. The third layer 33 may include a layer other than the layer that functions as the electron injection layer and the layer that functions as the electron transport layer. The third layer 33 is not limited to these materials.

For example, the light that is emitted from the organic layer 30 is substantially white light. In other words, the light that is emitted from the organic electroluminescent element 110 is white light. Here, “white light” is substantially white and includes, for example, white light that is reddish, yellowish, greenish, bluish, violet-tinted, etc. The color temperature of the light emitted from the organic layer 30 is, for example, not less than 2600 K and not more than 7000 K.

The first electrode 10 includes, for example, an oxide including at least one element selected from the group consisting of In, Sn, Zn, and Ti. The first electrode 10 may include, for example, gold, platinum, silver, copper, or a film (e.g., NESA, etc.) made using conductive glass including indium oxide, zinc oxide, tin oxide, indium tin oxide (ITO), fluorine-doped tin oxide (FTO), indium zinc oxide, etc. For example, the first electrode 10 functions as a positive electrode. The first electrode 10 is not limited to these materials.

The second electrode 20 includes, for example, at least one of aluminum or silver. For example, the second electrode 20 includes an aluminum film. Further, an alloy of silver and magnesium may be used as the second electrode 20. Calcium may be added to the alloy. For example, the second electrode 20 functions as a negative electrode. The second electrode 20 is not limited to these materials.

The first electrode 10 may be used as a negative electrode; the second electrode 20 may be used as a positive electrode; the second layer 32 may function as an electron injection layer or an electron transport layer; and the third layer 33 may function as a hole injection layer or a hole transport layer.

The first insulating layer 40 includes, for example, an organic insulating material such as a polyimide resin, an acrylic resin, polyvinyl phenol (PVP), PMMA, a fluorocarbon resin, etc. The first insulating layer 40 is not limited to these materials.

The second insulating layer 50 includes, for example, a silicon oxide film (e.g., SiO₂), a silicon nitride film (e.g., SiN), a silicon oxynitride film (e.g., SiON), or an inorganic insulating material of magnesium fluoride (MgF₂), lithium fluoride (LiF), aluminum fluoride (AlF₃), aluminum oxide (Al₂O₃), molybdenum oxide (MoOₓ), calcium fluoride (CaF), etc. The second insulating layer 50 includes, for example, a material having a gas barrier property. The second insulating layer 50 is not limited to these materials. The second insulating layer 50 may include, for example, an organic insulating material and an inorganic insulating material. For example, the material of the second insulating layer 50 may be any material having a density of not less than 2 g/cm³ and not more than 3.5 g/cm³.

The method for manufacturing the second insulating layer 50 may be a dry method or may be a wet method. The dry method may include, for example, vapor deposition, sputtering, CVD, etc. The wet method may include, for example, a sol-gel method, etc. For example, the material of the second insulating layer 50 includes magnesium fluoride. Thereby, for example, the second insulating layer 50 can be formed by vapor deposition. For example, the formation of the second insulating layer 50 can be easy.

The thickness (the length in the Z-axis direction) of the first electrode 10 is, for example, not less than 10 nm and not more than 500 nm. More favorably, the thickness is not less than 50 nm and not more than 200 nm. The thickness of the insulating portion 40a is, for example, not less than 1 μm and not more than 100 μm. The thickness of the organic layer 30 is, for example, not less than 10 nm and not more than 500 nm. The thickness of the second electrode 20 (the conductive portion 20a) is, for example, not less than 10 nm and not more than 300 nm. A width W1 (the length in the X-axis direction) of the conductive portion 20a is, for example, not less than 1 μm and not more than 500 μm. A pitch Pt1 of the multiple conductive portions 20a is, for example, not less than 2 μm and not more than 2000 μm. More favorably, the pitch Pt1 is not less than 2 μm and not more than 200 μm. The pitch Pt1 is, for example, the distance in the X-axis direction between the X-axis direction centers of two mutually-adjacent conductive portions 20a. A width W2 of the portion of the insulating portion 40a extending in the Y-axis direction is, for example, not less than 1 μm and not more than 1500 μm. A pitch Pt2 of the portion of the insulating portion 40a extending in the Y-axis direction is, for example, not less than 2 μm and not more than 2000 μm.

FIG. 5 is a plan view schematically showing a portion of another organic electroluminescent element according to the first embodiment.

In the example as shown in FIG. 5, the multiple openings 20b of the second electrode 20 are arranged in the X-axis direction and arranged in the Y-axis direction. In other words, in the example, the multiple openings 20b are arranged in a two-dimensional matrix configuration. For example, the conductive portion 20a has a lattice configuration. Thus, the second electrode 20 (the conductive portion 20a) is not limited to a stripe configuration and may have a lattice configuration.

In the conductive portion 20a having the lattice configuration, a width Wx of the portions extending in the Y-axis direction and arranged in the X-axis direction is not less than 1 μm and not more than 500 μm. A pitch Px of the portions extending in the Y-axis direction and arranged in the X-axis direction is, for example, not less than 2 μm and not more than 2000 μm. A width Wy of the portions extending in the X-axis direction and arranged in the Y-axis direction is not less than 1 μm and not more than 500 μm. A pitch Py of the portions extending in the X-axis direction and arranged in the Y-axis direction is, for example, not less than 2 μm and not more than 2000 μm.

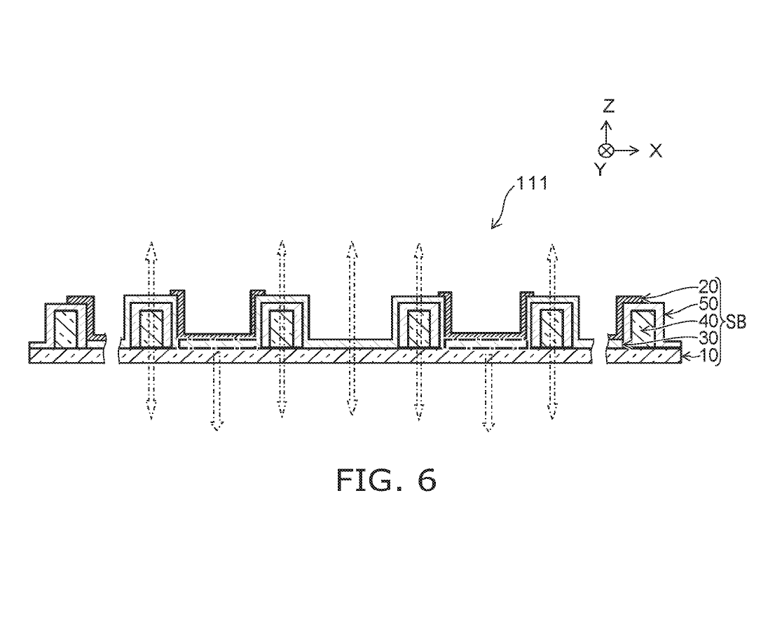

FIG. 6 is a cross-sectional view schematically showing another organic electroluminescent element according to the first embodiment.

In the organic electroluminescent element 111 as shown in FIG. 6, the second insulating layer 50 covers the entire first insulating layer 40. In the organic electroluminescent element 111, for example, the first insulating layer 40 is covered with the first electrode 10 and the second insulating layer 50. In other words, the first insulating layer 40 is sealed with the first electrode 10 and the second insulating layer 50. Thereby, in the organic electroluminescent element 111, for example, the penetration of the moisture into the organic layer 30 can be suppressed more appropriately. For example, the storage life of the organic electroluminescent element 111 can be longer.

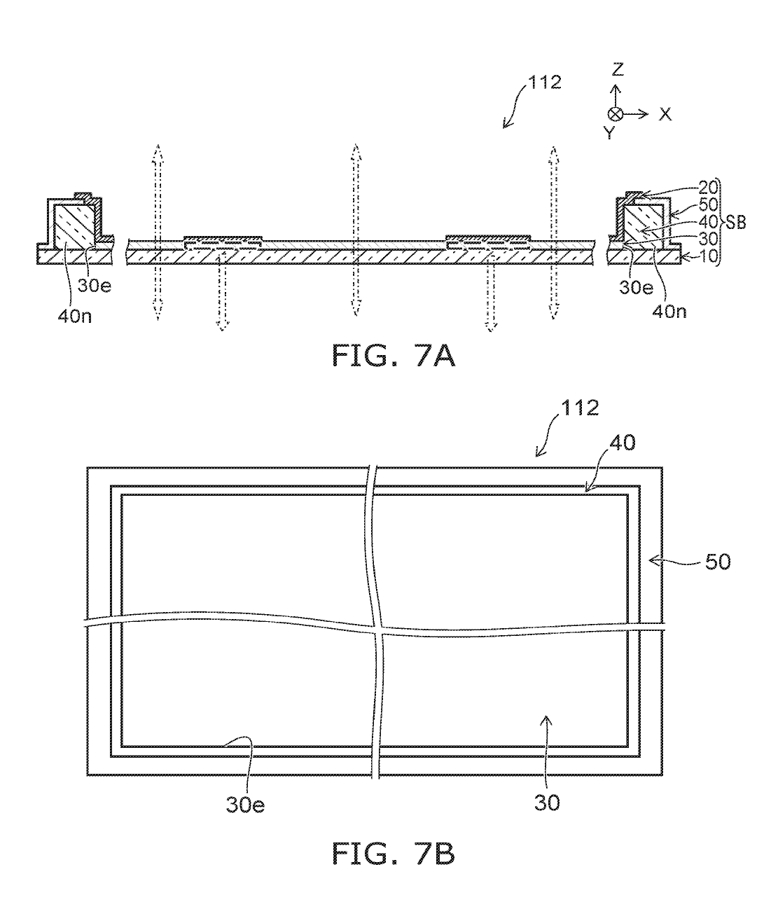

FIG. 7A and FIG. 7B are schematic views showing another organic electroluminescent element according to the first embodiment.

FIG. 7A is a cross-sectional view schematically showing the organic electroluminescent element 112. FIG. 7B is a plan view schematically showing the organic electroluminescent element 112. The second electrode 20 is not shown in FIG. 7B for convenience of illustration.

In the organic electroluminescent element 112 as shown in FIG. 7A, the first insulating layer 40 does not extend between the first electrode 10 and the organic layer 30. Thus, the first insulating layer 40 may not necessarily be provided between the first electrode 10 and the organic layer 30. The configuration of the first insulating layer 40 may be, for example, any configuration such that the insulating portion 40a can cover at least a portion of the outer edge 30e of the organic layer 30. For example, it is sufficient for the configuration of the first insulating layer 40 to be such that at least a portion of the organic layer 30 can be disposed between a pair of mutually-adjacent insulating portions 40a.

In the organic electroluminescent element 112 as well, the penetration of the moisture into the outer edge 30e of the organic layer 30 can be suppressed by the second insulating layer 50. The storage life of the organic electroluminescent element 112 can be longer.

In the organic electroluminescent element 112 as shown in FIG. 7B, the first insulating layer 40 has an annular configuration surrounding the outer edge 30e of the organic layer 30. In the organic electroluminescent element 112, the insulating portion 40a of the first insulating layer 40 covers the entire outer edge 30e.

In the organic electroluminescent element 112, the second insulating layer 50 has an annular configuration that at least covers the outer edge 40e of the first insulating layer 40. For example, the second insulating layer 50 covers the entire non-laminated portion 40n of the first insulating layer 40. Thereby, for example, the penetration of the moisture into the outer edge 30e can be suppressed more appropriately. For example, the storage life of the organic electroluminescent element 112 can be longer.

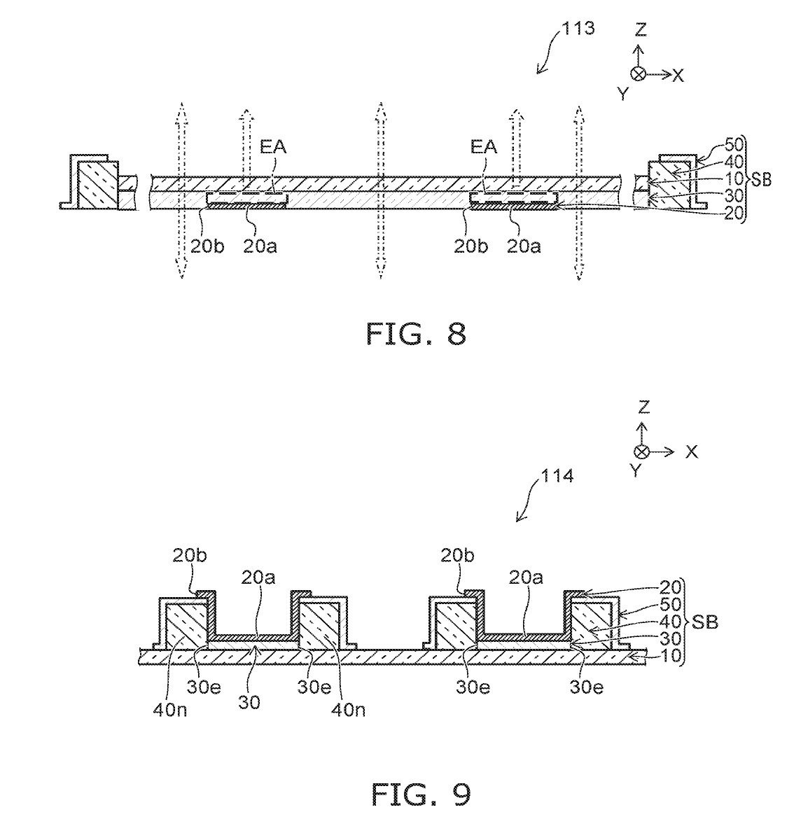

FIG. 8 is a cross-sectional view schematically showing another organic electroluminescent element according to the first embodiment.

In the organic electroluminescent element 113 as shown in FIG. 8, the second electrode 20, the organic layer 30, and the first electrode 10 are stacked in this order in the stacked body SB.

The first electrode 10, the organic layer 30, and the second electrode 20 are stacked in this order in the stacked body SB in the organic electroluminescent elements 110 to 112 recited above. In such a case, for example, the light is irradiated toward the side of the light-transmissive substrate supporting the first electrode 10. In other words, the organic electroluminescent elements 110 to 112 have bottom-emission type structures.

In the organic electroluminescent element 113, the stacking order of the stacked body SB is the opposite of that of the organic electroluminescent elements 110 to 112. In the organic electroluminescent element 113, for example, the light is irradiated toward the opposite side of the substrate supporting the second electrode 20 and the organic layer 30. In other words, the light is irradiated toward the first electrode 10 side. In other words, the organic electroluminescent element 113 has a top-emission type structure.

Thus, the first insulating layer 40 and the second insulating layer 50 are provided in the top-emission type organic electroluminescent element 113. Thereby, in the organic electroluminescent element 113 as well, the penetration of the moisture into the outer edge 30e of the organic layer 30 can be suppressed. The storage life of the organic electroluminescent element 113 can be longer.

In the organic electroluminescent element 113, the first insulating layer 40 has an annular configuration surrounding the outer edge 30e of the organic layer 30. In the organic electroluminescent element 113, the second insulating layer 50 has an annular configuration surrounding the first insulating layer 40. Thereby, for example, the penetration of the moisture into the outer edge 30e can be suppressed more appropriately. For example, the storage life of the organic electroluminescent element 113 can be longer.

FIG. 9 is a cross-sectional view schematically showing another organic electroluminescent element according to the first embodiment.

In the organic electroluminescent element 114 as shown in FIG. 9, the multiple organic layers 30 are provided in the stacked body SB. For example, when projected onto the X-Y plane, the multiple organic layers 30 are disposed respectively at positions overlapping the multiple conductive portions 20a. Thus, the organic layers 30 may be provided only in the portions between the first electrode 10 and the conductive portions 20a.

The first insulating layer 40 and the second insulating layer 50 are provided in the organic electroluminescent element 114. For example, the first insulating layer 40 surrounds each of the multiple organic layers 30. For example, the second insulating layer 50 covers the non-laminated portion 40n of the first insulating layer 40. In other words, the second insulating layer 50 covers the outer side of a pair of insulating portions 40a provided to have the organic layer 30 interposed on the inner side of the pair of insulating portions 40a. Thereby, in the organic electroluminescent element 114 as well, the penetration of the moisture into the outer edge 30e of each of the multiple organic layers 30 can be suppressed. The storage life of the organic electroluminescent element 114 can be longer.

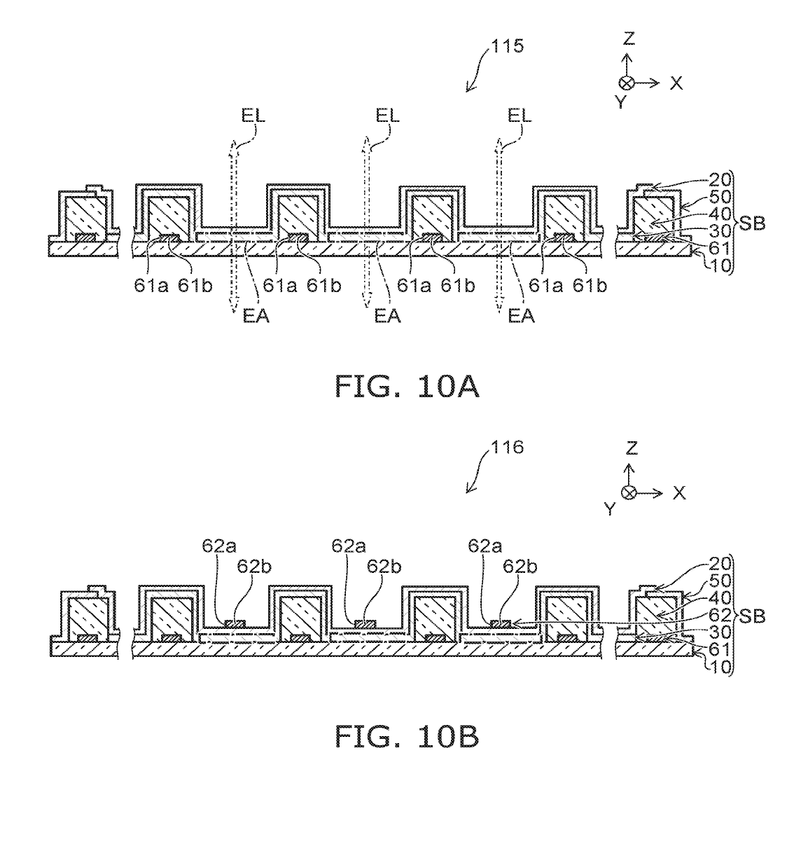

FIG. 10A and FIG. 10B are cross-sectional views schematically showing another organic electroluminescent element according to the first embodiment.

In the organic electroluminescent element 115 as shown in FIG. 10A, the second electrode 20 does not have the opening 20b. For example, the second electrode 20 is provided on the entire organic layer 30. In the example, the second electrode 20 is light-transmissive. The second electrode 20 is, for example, transparent.

Thereby, in the organic electroluminescent element 115, the emitted light EL that is emitted from the light-emitting region EA when the voltage is applied to the organic layer 30 via the first electrode 10 and the second electrode 20 is emitted outside the organic electroluminescent element 115 via the first electrode 10 and emitted outside the organic electroluminescent element 115 via the second electrode 20. In other words, the organic electroluminescent element 115 is a two-side emitting type.

In the organic electroluminescent element 115, the stacked body SB further includes a first interconnect layer 61. The first interconnect layer 61 is provided between the first electrode 10 and the first insulating layer 40. The first interconnect layer 61 includes an interconnect portion 61b and an opening 61a. A portion of the first electrode 10 is exposed in the opening 61a. The first interconnect layer 61 includes, for example, the multiple interconnect portions 61b and the multiple openings 61a. In the example, the multiple openings 61a extend in the Y-axis direction and are arranged in the X-axis direction. The multiple interconnect portions 61b are provided respectively in each of the regions between the multiple openings 61a. In other words, in the example, the pattern configuration of the first interconnect layer 61 is a stripe configuration. For example, when projected onto the X-Y plane, the multiple interconnect portions 61b are disposed respectively at positions overlapping the multiple insulating portions 40a. The multiple interconnect portions 61b may not necessarily overlap the multiple insulating portions 40a.

The first interconnect layer 61 is electrically connected to the first electrode 10. For example, the first interconnect layer 61 contacts the first electrode 10. The conductivity of the first interconnect layer 61 is higher than the conductivity of the first electrode 10. The first interconnect layer 61 is light-reflective. The light reflectance of the first interconnect layer 61 is higher than the light reflectance of the first electrode 10. The first interconnect layer 61 is, for example, a metal interconnect. For example, the first interconnect layer 61 functions as an auxiliary electrode that conducts the current flowing in the first electrode 10. Thereby, in the organic electroluminescent element 115, for example, the amount of current that flows in the first electrode 10 can be more uniform. For example, the light emission luminance can be more uniform in the plane.

In the organic electroluminescent element 115 as well, the penetration of the moisture into the outer edge 30e of the organic layer 30 can be suppressed by providing the first insulating layer 40 and the second insulating layer 50. The storage life of the organic electroluminescent element 115 can be longer.

The light-transmissive second electrode 20 may include, for example, the materials described in reference to the first electrode 10. The light-transmissive second electrode 20 may be, for example, a metal material such as Mg—Ag, etc. For the metal material, the thickness of the second electrode 20 is set to be not less than 5 nm and not more than 20 nm. Thereby, the appropriate light transmissivity can be obtained.

The first interconnect layer 61 includes, for example, at least one element selected from the group consisting of Mo, Ta, Nb, Al, Ni, and Ti. The first interconnect layer 61 may be, for example, a mixed film including the elements selected from the group. The first interconnect layer 61 may be a stacked film including these elements. The first interconnect layer 61 may include, for example, a stacked film of Nb/Mo/Al/Mo/Nb. For example, the first interconnect layer 61 functions as an auxiliary electrode that suppresses the potential drop of the first electrode 10. The first interconnect layer 61 may function as a lead electrode to supply current. The first interconnect layer 61 is not limited to these materials.

In the organic electroluminescent element 116 as shown in FIG. 10B, the stacked body SB further includes a second interconnect layer 62. The second interconnect layer 62 is provided on the second electrode 20. The second interconnect layer 62 includes an interconnect portion 62b and an opening 62a. A portion of the second electrode 20 is exposed in the opening 62a. The second interconnect layer 62 includes, for example, the multiple interconnect portions 62b and the multiple openings 62a. In the example, the multiple openings 62a extend in the Y-axis direction and are arranged in the X-axis direction. The multiple interconnect portions 62b are provided respectively in each of the regions between the multiple openings 62a. In other words, in the example, the pattern configuration of the second interconnect layer 62 is a stripe configuration. In the example, when projected onto the X-Y plane, each of the multiple interconnect portions 62b is disposed at a position that does not overlap the multiple insulating portions 40a. For example, when projected onto the X-Y plane, the multiple interconnect portions 62b may be disposed respectively at positions overlapping the multiple insulating portions 40a.

The second interconnect layer 62 is electrically connected to the second electrode 20. For example, the second interconnect layer 62 contacts the second electrode 20. The conductivity of the second interconnect layer 62 is higher than the conductivity of the second electrode 20. The second interconnect layer 62 is light-reflective. The light reflectance of the second interconnect layer 62 is higher than the light reflectance of the second electrode 20. The second interconnect layer 62 is, for example, a metal interconnect. For example, the second interconnect layer 62 functions as an auxiliary electrode that conducts the current flowing in the second electrode 20. Thereby, in the organic electroluminescent element 116, for example, the amount of current that flows in the second electrode 20 can be more uniform. For example, the light emission luminance can be more uniform in the plane.

For example, the second interconnect layer 62 may be provided between the second electrode 20 and the organic layer 30. The pattern configuration of the second interconnect layer 62 may be a lattice configuration. The second interconnect layer 62 may include, for example, the material described in reference to the first interconnect layer 61.

In the organic electroluminescent element 116 as well, the penetration of the moisture into the outer edge 30e of the organic layer 30 can be suppressed by providing the first insulating layer 40 and the second insulating layer 50. The storage life of the organic electroluminescent element 116 can be longer.

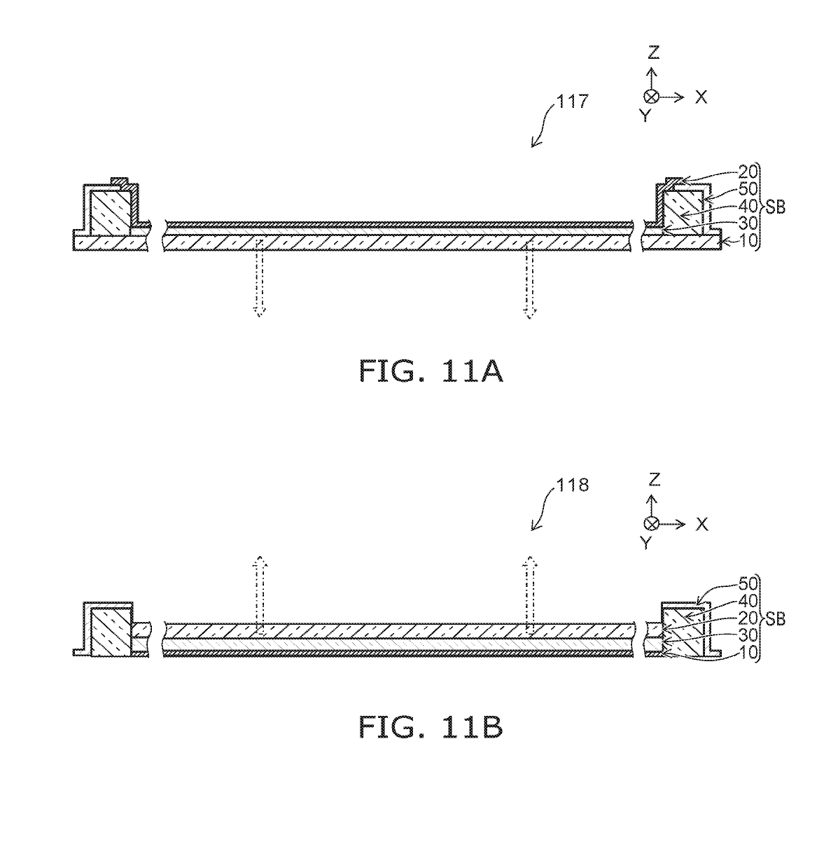

FIG. 11A and FIG. 11B are cross-sectional views schematically showing other organic electroluminescent elements according to the first embodiment.

In an organic electroluminescent element 117 and an organic electroluminescent element 118 as shown in FIG. 11A and FIG. 11B, the second electrode 20 does not have the opening 20b. For example, the second electrode 20 is provided on the entire organic layer 30. In the example, one of the first electrode 10 or the second electrode 20 is light-reflective; and the other is light-transmissive. In other words, the organic electroluminescent element 117 and the organic electroluminescent element 118 are single-side emitting type elements that are not light-transmissive.

In the organic electroluminescent element 117, the first electrode 10 is light-transmissive; and the second electrode 20 is light-reflective. In other words, the organic electroluminescent element 117 is the bottom-emission type. In the organic electroluminescent element 118, the first electrode 10 is light-reflective; and the second electrode 20 is light-transmissive. In other words, the organic electroluminescent element 118 is the top-emission type.

In the organic electroluminescent elements 117 and 118 as well, the penetration of the moisture into the outer edge 30e of the organic layer 30 can be suppressed by providing the first insulating layer 40 and the second insulating layer 50. The storage lives of the organic electroluminescent elements 117 and 118 can be longer.

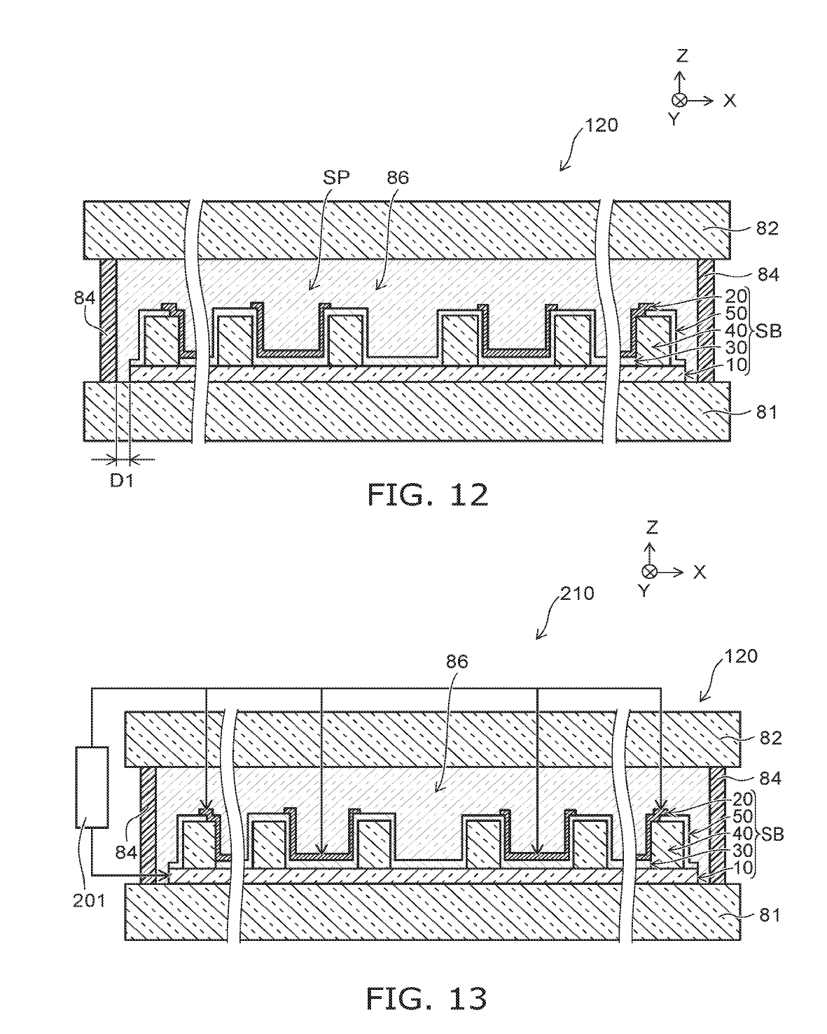

FIG. 12 is a cross-sectional view schematically showing another organic electroluminescent element according to the first embodiment.

As shown in FIG. 12, the organic electroluminescent element 120 further includes a first substrate 81, a second substrate 82, and a sealing unit 84.

The first substrate 81 and the second substrate 82 are light-transmissive. The first substrate 81 and the second substrate 82 are, for example, transparent. The second substrate 82 is arranged with the first substrate 81 in the Z-axis direction. The first electrode 10 is provided between the first substrate 81 and the second substrate 82. The second electrode 20 is provided between the first electrode 10 and the second substrate 82. In other words, the stacked body SB is provided between the first substrate 81 and the second substrate 82.

In other words, the stacked body SB is provided on the first substrate 81. The second substrate 82 is provided on the stacked body SB. More specifically, the first electrode 10 is provided on the first substrate 81. The organic layer 30 is provided on the first electrode 10. The second electrode 20 is provided on the organic layer 30. The second substrate 82 is provided on the second electrode 20.

In the example, the stacked body SB is the same as the stacked body SB described in reference to the organic electroluminescent element 110. The stacked body SB may be the stacked body SB described in reference to the organic electroluminescent elements 111 to 118. In the case of the single-side emitting type stacked body SB that is not light-transmissive as described in reference to the organic electroluminescent elements 117 and 118, the second substrate 82 that opposes the second electrode 20 may not be light-transmissive. For example, the first insulating layer 40 and the second insulating layer 50 may be provided on the first substrate 81 in the case where the first insulating layer 40 that does not extend between the first electrode 10 and the organic layer 30 is used as in the organic electroluminescent elements 112, 113, 117, and 118.

For example, the sealing unit 84 is provided in an annular configuration along the outer edges of the first substrate 81 and the second substrate 82 and bonds the first substrate 81 to the second substrate 82. The sealing unit 84 surrounds the first electrode 10, the second electrode 20, the organic layer 30, the first insulating layer 40, and the second insulating layer 50. In other words, the sealing unit 84 surrounds the stacked body SB. Thereby, the stacked body SB is sealed with the first substrate 81, the second substrate 82, and the sealing unit 84. Thus, the penetration of the moisture into the organic layer 30 can be suppressed more appropriately by sealing the stacked body SB.

A distance D1 between the sealing unit 84 and the second insulating layer 50 is, for example, not less than 100 μm and not more than 5000 μm. More specifically, the distance D1 is the minimum distance between the sealing unit 84 and the second insulating layer 50. The penetration of the moisture into the outer edge 30e of the organic layer 30 is suppressed more as the length of the distance D1 increases. On the other hand, the light emission surface area of the organic electroluminescent element 120 undesirably decreases as the distance D1 increases. In the organic electroluminescent element 120, the second insulating layer 50 is provided in the stacked body SB. Thereby, for example, compared to the case where the second insulating layer 50 is not provided, the stacked body SB can be proximal to the sealing unit 84. For example, even in the case where the distance D1 is not less than 100 μm and not more than 5000 μm, the penetration of the moisture into the organic layer 30 can be suppressed appropriately. Thus, in the organic electroluminescent element 120, the decrease of the light emission surface area of the element also can be suppressed while suppressing the penetration of the moisture into the organic layer 30.

In the organic electroluminescent element 120, the distance in the Z-axis direction between the first substrate 81 and the second substrate 82 is regulated by the sealing unit 84. For example, this configuration is realized by including a spacer having a granular configuration (not shown) in the sealing unit 84. For example, multiple spacers having granular configurations are dispersed in the sealing unit 84; and the distance between the first substrate 81 and the second substrate 82 is regulated by the diameters of the multiple spacers.

In the organic electroluminescent element 120, the thickness (the length along the Z-axis direction) of the sealing unit 84 is, for example, not less than 1 μm and not more than 100 μm. More favorably, the thickness is, for example, not less than 5 μm and not more than 20 μm. Thereby, for example, the penetration of the moisture, etc., can be suppressed. For example, the thickness of the sealing unit 84 is substantially the same as the diameters of the spacers dispersed in the sealing unit 84.

In the example, the organic electroluminescent element 120 further includes an intermediate layer 86. The intermediate layer 86 is filled into a space SP on an inner side surrounded with the first substrate 81, the second substrate 82, and the sealing unit 84. The second insulating layer 50 is provided between the first insulating layer 40 and the intermediate layer 86. For example, the second insulating layer 50 contacts the intermediate layer 86.

The intermediate layer 86 includes a desiccant. In other words, the intermediate layer 86 is desiccant. For example, the intermediate layer 86 also may be oxygen-adsorptive. The desiccant material includes, for example, calcium oxide, barium oxide, strontium oxide, magnesium oxide, calcium sulfate, calcium chloride, lithium chloride, calcium bromide, potassium carbonate, copper sulfate, sodium sulfate, zinc chloride, zinc bromide, cobalt chloride, phosphorus pentoxide, silica gel, aluminum oxide, zeolite, an organometallic complex, etc. For example, the desiccant material is dispersed in a resin material. The resin material includes, for example, an acrylic resin, a methacrylic resin, a urethane resin, polyisoprene, a cellulosic resin, a triazine resin, an epoxy resin, etc. Thus, the intermediate layer 86 includes a resin material. Thereby, for example, when bonding the first substrate 81 to the second substrate 82, the second substrate 82 contacts the stacked body SB; and the undesirable scratching of the stacked body SB can be suppressed.

Thus, the space SP is filled with the intermediate layer 86 including the desiccant material. Thereby, the penetration of the moisture into the organic layer 30 can be suppressed more appropriately. The intermediate layer 86 is provided as necessary and is omissible. The space SP may be, for example, an air layer. For example, an inert gas such as N₂, Ar, etc., may be filled into the space SP. The intermediate layer 86 may not include the desiccant material. The intermediate layer 86 may include, for example, the resin material recited above that does not include the desiccant material.

The first substrate 81 and the second substrate 82 include, for example, a glass substrate, a resin substrate, etc. A sealing unit 85 includes, for example, an ultraviolet-curing resin, etc.

### Second Embodiment

FIG. 13 is schematic view showing a lighting device according to a second embodiment.

As shown in FIG. 13, the lighting device 210 according to the embodiment includes the organic electroluminescent element according to the first embodiment (e.g., the organic electroluminescent element 120) and a power supply unit 201.

The power supply unit 201 is electrically connected to the first electrode 10 and the second electrode 20. The power supply unit 201 supplies a current to the organic layer 30 via the first electrode 10 and the second electrode 20. Thereby, light is emitted from the organic electroluminescent element 120 (the organic layer 30) due to the supply of the current from the power supply unit 201.

According to the lighting device 210 according to the embodiment, a lighting device including an organic electroluminescent element having a long storage life can be provided.

### Third Embodiment

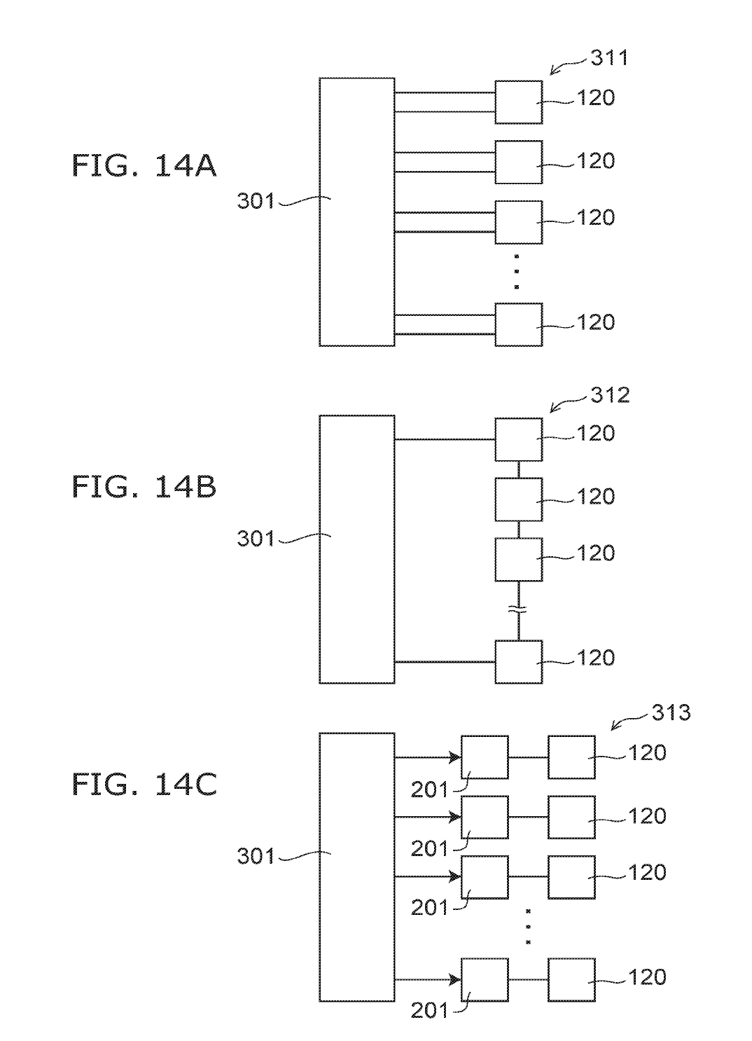

FIG. 14A to FIG. 14C are schematic views showing lighting systems according to a third embodiment.

As shown in FIG. 14A, a lighting system 311 according to the embodiment includes multiple organic electroluminescent elements according to the first embodiment (e.g., the organic electroluminescent elements 120) and a controller 301.

The controller 301 is electrically connected to each of the multiple organic electroluminescent elements 120 and controls the lit state/unlit state of each of the multiple organic electroluminescent elements 120. For example, the controller 301 is electrically connected to the first electrode 10 and the second electrode 20 of each of the multiple organic electroluminescent elements 120. Thereby, the controller 301 individually controls the lit state/unlit state of each of the multiple organic electroluminescent elements 120.

In a lighting system 312 as shown in FIG. 14B, the multiple organic electroluminescent elements 120 are connected in series. The controller 301 is electrically connected to the first electrode 10 of one organic electroluminescent element 120 of the multiple organic electroluminescent elements 120. The controller 301 also is electrically connected to the second electrode 20 of one other organic electroluminescent element 120 of the multiple organic electroluminescent elements 120. Thereby, the controller 301 collectively controls the lit state/unlit state of each of the multiple organic electroluminescent elements 120. Thus, the controller 301 may control the lit state/unlit state of each of the multiple organic electroluminescent elements 120 individually or collectively.

The power supply unit 201 is further included in a lighting system 313 as shown in FIG. 14C. In the example, the lighting system 313 includes the multiple power supply units 201. The multiple power supply units 201 are electrically connected respectively to the multiple organic electroluminescent elements 120.

In the lighting system 313, the controller 301 is electrically connected to each of the multiple power supply units 201. In other words, in the lighting system 313, the controller 301 is electrically connected to each of the multiple organic electroluminescent elements 120 via the multiple power supply units 201. For example, the controller 301 inputs a control signal to each of the power supply units 201. Each of the power supply units 201 supplies a current to the organic electroluminescent element 120 according to the control signal from the controller 301 and causes the organic electroluminescent element 120 to turn on.

Thus, the controller 301 may control the lit state/unlit state of the multiple organic electroluminescent elements 120 via the power supply units 201. In the example, the multiple power supply units 201 are connected respectively to the multiple organic electroluminescent elements 120. This is not limited thereto; for example, one power supply unit 201 may be connected to the multiple organic electroluminescent elements 120. For example, the one power supply unit 201 may be able to selectively supply currents to the multiple organic electroluminescent elements 120 according to control signals from the controller 301. The electrical connection between the controller 301 and the power supply unit 201 may be wired or may be wireless. For example, the control signals from the controller 301 may be input to the power supply unit 201 by wireless communication.

According to the lighting systems 311 to 313 according to the embodiment, a lighting system including an organic electroluminescent element having a long storage life can be provided.

According to embodiments of the invention, an organic electroluminescent element, a lighting device, and a lighting system that have a long storage life can be provided, for example.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel. In the specification of the application, a state of “provided on” includes a state to be provided having another element being inserted therebetween in addition to a state to be provided directly contacting. A state of “stacking” includes a state to be stacked having another element inserted therebetween in addition to a state to be provided directly contacting each other. A state of “electrically connected” includes a state to be connected through another electrical member in addition to a state to be connected directly contacting.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in organic electroluminescent elements such as first electrode, second electrode, organic layer, first insulating layer, second insulating layer, first substrate, second substrate, sealing unit, intermediate layer, and power supply unit included in lighting devices, and controller included in lighting systems, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all organic electroluminescent elements, lighting devices, and lighting systems practicable by an appropriate design modification by one skilled in the art based on the organic electroluminescent elements, the lighting devices, and the lighting systems described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An organic electroluminescent element, comprising:
a first electrode;
a first insulating layer provided on the first electrode, the first insulating layer having an opening;
an organic layer provided on the first electrode, at least a portion of the organic layer being provided in the opening;
a second electrode, at least a portion of the second electrode being provided on the organic layer; and
a second insulating layer covering at least a portion of an outer edge of the first insulating layer, a density of the second insulating layer being higher than a density of the first insulating layer.

2. The element according to claim 1, wherein
the first insulating layer includes a laminated portion and a non-laminated portion, the laminated portion overlapping each of the organic layer and the second electrode, the non-laminated portion being other than the laminated portion, and
the second insulating layer covers the non-laminated portion of the first insulating layer.

3. The element according to claim 1, wherein the second insulating layer covers the entire first insulating layer.

4. The element according to claim 1, wherein
the first insulating layer includes an organic insulating material, and
the second insulating layer includes an inorganic insulating material.

5. The element according to claim 1, further comprising:
a first substrate, the first substrate being light-transmissive;
a second substrate arranged with the first substrate in a first direction; and
a sealing unit provided along outer edges of the first substrate and the second substrate, the sealing unit bonding the first substrate to the second substrate,
the first electrode being provided between the first substrate and the second substrate,
the second electrode being provided between the first electrode and the second substrate,
the sealing unit surrounding the first electrode, the second electrode, the organic layer, the first insulating layer, and the second insulating layer.

6. The element according to claim 5, further comprising an intermediate layer filled into an inner side surrounded with the first substrate, the second substrate, and the sealing unit.

7. The element according to claim 6, wherein the intermediate layer includes a desiccant material.

8. The element according to claim 1, wherein the first electrode is light-transmissive, and the second electrode is light-reflective.

9. A lighting device, comprising:
an organic electroluminescent element including
a first electrode,
a first insulating layer provided on the first electrode, the first insulating layer having an opening,
an organic layer provided on the first electrode, at least a portion of the organic layer being provided in the opening,
a second electrode, at least a portion of the second electrode being provided on the organic layer, and
a second insulating layer covering at least a portion of an outer edge of the first insulating layer, a density of the second insulating layer being higher than a density of the first insulating layer; and
a power supply unit electrically connected to the first electrode and the second electrode, the power supply unit supplying a current to the organic layer via the first electrode and the second electrode.

10. A lighting system, comprising:
a plurality of organic electroluminescent elements, each of the plurality of organic electroluminescent elements including
a first electrode,
a first insulating layer provided on the first electrode, the first insulating layer having an opening,
an organic layer provided on the first electrode, at least a portion of the organic layer being provided in the opening,
a second electrode, at least a portion of the second electrode being provided on the organic layer, and
a second insulating layer covering at least a portion of an outer edge of the first insulating layer, a density of the second insulating layer being higher than a density of the first insulating layer; and
a controller electrically connected to each of the plurality of organic electroluminescent elements, the controller controlling a lit state/unlit state of each of the plurality of organic electroluminescent elements.
